(19) United States
(12) Patent Application Publication
(10) Pub. No.: US 2025/0201567 A1
(43) Pub. Date: Jun. 19, 2025

(54) SUBSTRATE PROCESSING METHOD, MANUFACTURING METHOD, AND SUBSTRATE PROCESSING APPARATUS

(71) Applicant: SEMES CO., LTD., Cheonan-si (KR)

(72) Inventor: Min Jung KIM, Bucheon-si (KR)

(73) Assignee: SEMES CO., LTD., Cheonan-si (KR)

(21) Appl. No.: 18/956,558

(22) Filed: Nov. 22, 2024

(30) Foreign Application Priority Data
Dec. 14, 2023 (KR) 10-2023-0181394

(51) Int. Cl. H01L 21/306

(52) U.S. Cl. CPC H01L 21/30604

(57) ABSTRACT

Disclosed is a method of processing a substrate, the method including: supplying an etchant for removing silicon germanium (SiGe) provided on a substrate to the substrate, the etchant being prepared with an etching chemical and an etching inhibitor, in which an etch rate for the silicon germanium and/or an etch selectivity for the silicon germanium is controlled by adjusting a proportion of at least one of the etching chemical and the etching inhibitor used in the preparation of the etchant.

### CROSS-REFERENCE TO RELATED APPLICATIONS

This application claims priority to and the benefit of Korean Patent Application No. 10-2023-0181394 filed in the Korean Intellectual Property Office on Dec. 14, 2023, the entire contents of which are incorporated herein by reference.

### TECHNICAL FIELD

The present invention relates to a substrate processing method, a manufacturing method, and a substrate processing apparatus.

### BACKGROUND ART

To manufacture semiconductor devices, various processes, such as photography, deposition, etching, and ion implantation, are performed on substrates, such as wafers. Among these, the etching process is a process that removes a film formed on a substrate. There are two types of etching processes: a wet etching process, which removes films in a wet manner by supplying an etchant to the substrate, and a dry etching process, which removes films in a dry manner by delivering plasma, ions, radicals, and the like to the substrate.

In the wet etching process, an etchant is supplied to the substrate to remove the film on the substrate. The substrate may be provided with a stack of films containing different materials, and in the wet etching process, it is necessary to selectively remove the film to be removed from among the above films.

### SUMMARY OF THE INVENTION

The present invention has been made in an effort to provide a substrate processing method, a substrate manufacturing method, and a substrate processing apparatus capable of efficiently processing a substrate.

The present invention has also been made in an effort to provide a substrate processing method, a substrate manufacturing method, and a substrate processing apparatus capable of selectively removing a film to be removed among various types of films stacked on a substrate.

The present invention has also been made in an effort to provide a substrate processing method, a substrate manufacturing method, and a substrate processing apparatus capable of controlling an etch rate and an etch selectivity for a film to be removed from a substrate.

The present invention has also been made in an effort to provide a substrate processing method, a substrate manufacturing method, and a substrate processing apparatus capable of effectively removing a film to be removed in manufacturing a semiconductor device having a 3D structure, such as a GAA structure or a CFET structure.

The problem to be solved by the present invention is not limited to the above-mentioned problems, and the problems not mentioned will be clearly understood by those skilled in the art from the descriptions below.

An exemplary embodiment of the present invention provides a method of processing a substrate, the method including: supplying an etchant for removing silicon germanium (SiGe) provided on a substrate to the substrate, the etchant being prepared with an etching chemical and an etching inhibitor, in which an etch rate for the silicon germanium and/or an etch selectivity for the silicon germanium is controlled by adjusting a proportion of at least one of the etching chemical and the etching inhibitor used in the preparation of the etchant.

According to the exemplary embodiment, in order to increase the etch rate for the silicon germanium, the proportion of the etching chemical may be increased, and in order to decrease the etch rate for the silicon germanium, the proportion of the etching chemical may be decreased.

According to the exemplary embodiment, the etching chemical is an acid catalyst including hydrogen peroxide, acetic acid, and hydrogen, hydrofluoric acid, or a combination thereof, in which the acid catalyst may be a stronger acid than the acetic acid.

According to the exemplary embodiment, a material different from the silicon germanium may be provided on the substrate, in order to increase the etch selectivity of the silicon germanium to the material, the proportion of the etching inhibitor may be increased, and in order to increase the etch selectivity of the silicon germanium to the material, the proportion of the etching inhibitor may be decreased.

According to the exemplary embodiment, the material may include at least one of silicon (Si) and silicon oxide (SiOx), and the etching inhibitor may be an inhibitor formed of a silicon etching inhibitor, a silicon oxide etching inhibitor, or a combination thereof.

According to the exemplary embodiment, a silicon material different from the silicon germanium may be further provided on the substrate, the etchant may selectively remove the silicon germanium from the silicon material, in a removal operation to remove the silicon germanium, the proportion of the etching chemical in the etchant may be a first proportion, and in a second removal operation, performed after the first removal operation, to remove the silicon germanium, the proportion of the etching chemical in the etchant may be adjusted to be a second proportion lower than the first proportion.

According to the exemplary embodiment, in the first removal operation, the proportion of the etching inhibitor used in the preparation of the etchant may be an A proportion, and in the second removal operation, the proportion of the etching inhibitor used in the preparation of the etchant may be adjusted to be a B proportion higher than the A proportion.

According to the exemplary embodiment, in a pre-etching operation, performed prior to the first removal operation, to remove only a portion of the silicon germanium, the proportion of the etching chemical used in the preparation of the etchant may be adjusted to be a P proportion lower than the first proportion or the second proportion.

According to the exemplary embodiment, the adjustment of the proportion of the etching chemical or the etching inhibitor may be accomplished by adjusting a supply flow rate per unit time of the etching chemical or the etching inhibitor supplied to a mixer where the etching chemical, the etching inhibitor, and deionized water are mixed.

Another exemplary embodiment of the present invention provides a manufacturing method in which a feature structure is provided in which a first layer composed of silicon germanium and a second layer composed of a silicon material different from the silicon germanium are alternately stacked, the silicon material being any one of silicon and silicon oxide, the manufacturing method including: an indent etching operation of supplying an etchant to the feature structure to remove only a portion of the first layer; and a full etching operation of supplying the etchant to the feature structure to remove a remainder of the first layer that has not been removed in the indent etching operation, in which a proportion of an etching chemical used in a preparation of the etchant supplied in the indent etching operation is different from a proportion of an etching chemical used in a preparation of the etchant supplied in the pull etching operation.

According to the exemplary embodiment, the proportion of the etching chemical used in the preparation of the etchant supplied in the indent etching operation may be lower than the proportion of the etching chemical used in the preparation of the etchant supplied in the full etching operation.

According to the exemplary embodiment, the proportion of the etching inhibitor used in the preparation of the etchant supplied in the indent etching operation may be higher than the proportion of the etching inhibitor used in the preparation of the etchant supplied in the full etching operation.

According to the exemplary embodiment, the full etching operation may include: a first removal operation; and a second removal operation performed after the first removal operation, and a proportion of the etching chemical used in the preparation of the etchant supplied in the first removal operation is higher than a proportion of the etching chemical used in the preparation of the etchant supplied in the second removal operation.

According to the exemplary embodiment, a proportion of the etching inhibitor used in the preparation of the etchant supplied in the first removal operation may be lower than a proportion of the etching inhibitor used in the preparation of the etchant supplied in the second removal operation.

According to the exemplary embodiment, a temperature of the etchant supplied in the first removal operation may be higher than a temperature of the etchant supplied in the second removal operation.

According to the exemplary embodiment, the manufacturing method may be a method of manufacturing a semiconductor device having a Gate All Around (GAA) structure.

According to the exemplary embodiment, the manufacturing method may be a method of manufacturing a semiconductor device having a Complementary FET (CFET) structure.

Still another exemplary embodiment of the present invention provides an apparatus for processing a substrate, the apparatus including: a substrate support chuck for supporting and rotating a substrate, the substrate being provided with a first layer composed of silicon germanium, and a second layer composed of a silicon material different from the silicon germanium; an etchant nozzle for supplying an etchant to the substrate supported by the substrate support chuck; an etchant supply unit for supplying the etchant to the etchant nozzle; and a controller configured to generate a control signal to control the etchant supply unit, in which the etchant supply unit includes: a first valve module connected with at least one etching chemical supply source, and at least one etching inhibitor supply source; a second valve module connected to a deionized water supply source; a mixer connected to the first valve module and the second valve module, and for mixing an etching chemical supplied by the etching chemical supply source, an etching inhibitor supplied by the etching inhibitor supply source, and deionized water supplied by the deionized water supply source; and an etchant supply line for supplying the etchant prepared by mixing in the mixer to the etchant nozzle, and the controller is configured to generate a control signal to control at least one of the etching chemical supply source and the first valve module, to regulate a supply flow rate per unit time of the etching chemical supplied to the mixer to control an etch rate for the first layer by the etchant.

According to the exemplary embodiment, the controller may be configured to generate a control signal to control at least one of the etching chemical supply source and or the first valve module, such that the supply flow rate per unit time of the etching chemical supplied to the mixer when performing indent etching, which removes only a portion of the first layer is different from the supply flow rate per unit time of the etching chemical supplied to the mixer when performing full etching, which removes a remainder of the first layer after the indent etching.

According to the exemplary embodiment, the etchant supply unit may include: a heater installed in the etchant supply line and for heating the etchant; and a chiller installed in the etchant supply line and for cooling the etchant, and the controller may be configured to generate a control signal to control the heater and the chiller such that, when performing the indent etching, the chiller cools the etchant and, when performing the full etching, the heater heats the etchant.

According to the exemplary embodiment of the present invention, it is possible to efficiently process a substrate.

Further, according to the exemplary embodiment of the present invention, it is possible to effectively supply an etchant onto a substrate, and improve efficiency of removing a film on the substrate.

Further, according to the exemplary embodiment of the present invention, it is possible to effectively remove process by-products that may be reattached to the substrate.

The effect of the present invention is not limited to the foregoing effects, and the not-mentioned effects will be clearly understood by those skilled in the art from the present specification and the accompanying drawings.

### BRIEF DESCRIPTION OF THE DRAWINGS

FIG. 1 is a top plan view of a substrate processing apparatus according to an exemplary embodiment of the present invention.

FIG. 2 is a cross-sectional view schematically illustrating a process chamber of FIG. 1.

FIG. 3 is a diagram illustrating an etchant supply unit that supplies an etchant to an etchant nozzle of FIG. 2.

FIG. 4 is a diagram illustrating processing a substrate in the process chamber of FIG. 2.

FIG. 5 is a diagram illustrating a comparative view of generation routes of peracetic acid without the addition of MSA and with the addition of MSA.

FIG. 6 is a flow chart illustrating a substrate processing method according to an exemplary embodiment of the present invention.

FIG. 7 is a diagram illustrating the removal of a film formed on a substrate when performing an indent etching of FIG. 6.

FIG. 8 is a diagram illustrating the appearance of a substrate after performing an indent etching operation, followed by an intermediate process on the substrate.

FIG. 9 is a diagram illustrating the removal of a film formed on the substrate when performing a pull etching of FIG. 6.

FIG. 10 is a diagram illustrating another view of a substrate in which a film formed on the substrate is removed by a substrate processing method according to an exemplary embodiment of the present invention.

Various features and advantages of the non-limiting exemplary embodiments of the present specification may become apparent upon review of the detailed description in conjunction with the accompanying drawings. The attached drawings are provided for illustrative purposes only and should not be construed to limit the scope of the claims. The accompanying drawings are not considered to be drawn to scale unless explicitly stated. Various dimensions in the drawing may be exaggerated for clarity.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

Hereinafter, a manufacturing method, a substrate processing method, and a substrate processing apparatus according to an exemplary embodiment of the present invention will be described in detail. The manufacturing method may be a method of manufacturing a semiconductor device. The substrate processing method may be processes corresponding to some of various processes required to manufacture the semiconductor device. Further, a substrate processing apparatus may be an apparatus for implementing the above substrate processing method for processing a substrate W, such as a wafer. Further, the substrate processing apparatus may correspond to a semiconductor device manufacturing apparatus capable of performing processes corresponding to some of the various processes required to manufacture the semiconductor devices described above.

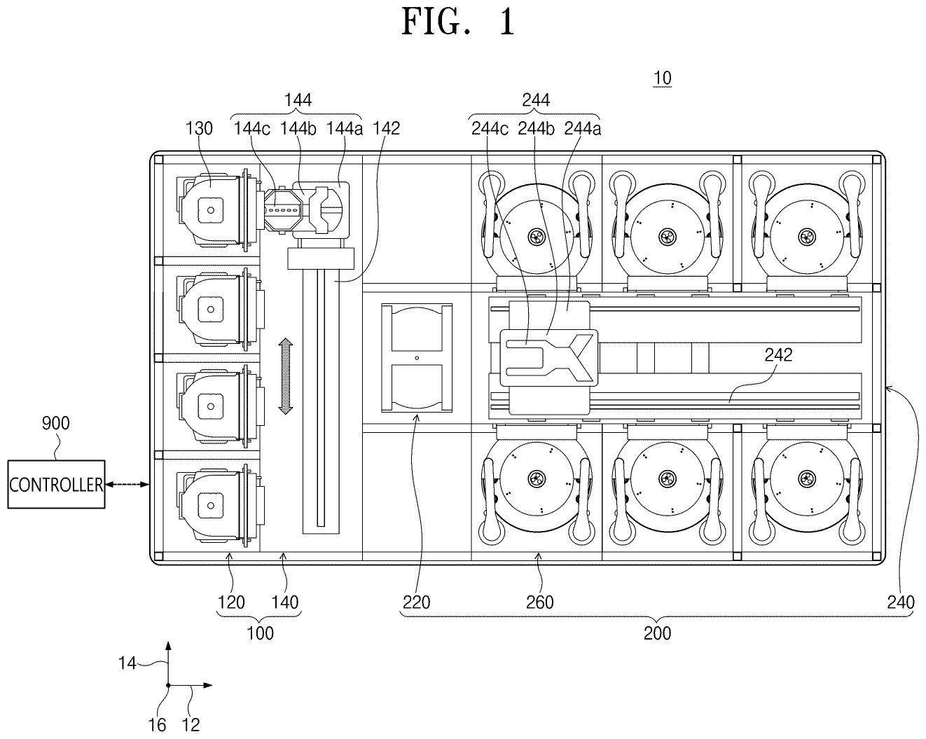

In the following, an exemplary embodiment of the present invention will be described in detail with reference to FIGS. 1 to 10. A substrate processing method, a manufacturing method, and a substrate processing apparatus described herein may be a substrate processing method, a manufacturing method, and a substrate processing apparatus for manufacturing semiconductor devices by processing a substrate, such as a wafer. In addition, a substrate processing method, a manufacturing method, and a substrate processing apparatus described herein may be a substrate processing method, a manufacturing method, and a substrate processing apparatus for manufacturing a semiconductor device including a 3D structure, such as a Gate All Around (GAA) structure or a Complementary FET (CFET) structure. Also, as used herein, “processing a substrate” may be understood to include not only processing the substrate itself, but also removing a film formed on the substrate.

FIG. 1 is a top plan view of a substrate processing apparatus according to an exemplary embodiment of the present invention.

Referring to FIG. 1, a substrate processing apparatus 10 includes an index module 100, a process processing module 200, and a controller 900. The Index module 100 includes a load port 120 and a transfer frame 140. The load port 120, the transfer frame 140, and the process processing module 20 are arranged in sequential rows. Hereinafter, a direction in which the load port 120, the transfer frame 140, and the process processing module 200 are arranged is referred to as a first direction 12, a direction perpendicular to the first direction 12 when viewed from above is referred to as a second direction 14, and a direction perpendicular to a plane including the first direction 12 and the second direction 14 is referred to as a third direction 16.

A carrier 130 in which a substrate W is accommodated is seated on the load port 120. A plurality of load ports 120 is provided and is arranged in a line along the second direction 14. The number of load ports 120 may be increased or decreased depending on process efficiency and footprint requirements of the process processing module 200. The carrier 130 is formed with a plurality of slots (not illustrated) for receiving the substrates W in a horizontal position relative to the ground. As the carrier 130, a Front Opening Unified Pod (FOUP) may be used.

The process processing module 200 includes a buffer unit 220, a transfer chamber 240, and a process chamber 260. The transfer chamber 240 may disposed so that a longitudinal direction thereof is parallel to the first direction. The process chambers 260 may be disposed at opposite sides of the transfer chamber 240. On one side of the transfer chamber 240 and on the other side of the transfer chamber 240, the process chambers 260 are provided to be symmetrical with respect to the transfer chamber 240. On one side of the transfer chamber 240, a plurality of process chambers 260 are provided. Some of the process chambers 260 may be disposed in the longitudinal direction of the transfer chamber 240. Further, some of the plurality of process chambers 260 may be disposed to be stacked on each other. That is, the plurality of process chambers 260 may be disposed in an arrangement of A×B at one side of the transfer chamber 240. Here, A is the number of process chambers 260 provided in a line along the first direction 12, and B is the number of process chambers 260 provided in a line along the third direction 16. When four or six process chambers 260 are provided at one side of the transfer chamber 240, the process chambers 260 may be disposed in an arrangement of 2×2 or 3×2. The number of process chambers 260 may be increased or decreased. Unlike the foregoing, the process chamber 260 may be provided only to one side of the transfer chamber 240. In addition, the process chamber 260 may be provided as a single layer on one side and both sides of the transfer chamber 240.

The buffer unit 220 is disposed between the transfer frame 140 and the transfer chamber 240. The buffer unit 220 may provide a space in which the substrate W stays before the substrate W is transferred between the transfer chamber 240 and the transfer frame 140. A slot (not illustrated) in which the substrate W is placed is provided inside the buffer unit 220. A plurality of slots (not illustrated) is provided so as to be spaced apart from each other in the third direction 16. A surface of the buffer unit 220 facing the transfer frame 140 and a surface of the buffer unit 220 facing the transfer chamber 240 may be opened.

The transfer frame 140 transfers the substrate W between the carrier 130 seated at the load port 120 and the buffer unit 220. An index rail 142 and an index robot 144 are provided to the transfer frame 140. A longitudinal direction of the index rail 142 is provided to be parallel to the second direction 14. The index robot 144 is installed on the index rail 142, and linearly moves in the second direction 14 along the index rail 142. The index robot 144 includes a base 144a, a body 144b, and an index arm 144c. The base 144a is installed to be movable along the index rail 142. The body 144b is coupled to the base 144a. The body 144b is provided to be movable in the third direction 16 on the base 144a. Further, the body 144b is provided to be rotatable on the base 144a. The index arm 144c is coupled to the body 144b and is provided to be movable forwardly and backwardly with respect to the body 144b. A plurality of index arms 144c is provided to be individually driven. The index arms 144c are disposed to be stacked in the state of being spaced apart from each other in the third direction 16. Some of the index arms 144c may be used when the substrate W is transferred from the process processing module 20 to the carrier 130, and another some of the plurality of index arms 144c may be used when the substrate W is transferred from the carrier 130 to the process processing module 200. This may prevent particles generated from the substrate W before the process processing from being attached to the substrate W after the process processing in the process of loading and unloading the substrate W by the index robot 144.

The transfer chamber 2400 transfers the substrate W between the buffer unit 2200 and the process chamber 260, and between the process chambers 260. A guide rail 242 and a main robot 244 are provided to the transfer chamber 240. The guide rail 242 is disposed so that a longitudinal direction thereof is parallel to the first direction 12. The main robot 244 is installed on the guide rail 242 and linearly moved along the first direction 12 on the guide rail 242. The main robot 244 includes a base 244a, a body 244b, and a main arm 244c. The base 244a is installed to be movable along the guide rail 242. The body 244b is coupled to the base 244a. The body 244b is provided to be movable in the third direction 16 on the base 244a. Further, the body 244b is provided to be rotatable on the base 244a. The main arm 244c is coupled to the body 244b, and provided to be movable forwardly and backwardly with respect to the body 244b. A plurality of main arms 244c is provided to be individually driven. The main arms 244c are disposed to be stacked in the state of being spaced apart from each other in the third direction 16.

The process chamber 260 performs a liquid treatment process on the substrate W. The process chamber 260 may supply the substrate W with an etchant to remove a film formed on the substrate W. The process chambers 260 may have different structures depending on the type of liquid treatment process being performed. Alternatively, each of the process chambers 260 may have the same structure. Optionally, the process chambers 260 may be divided into a plurality of groups, such that process chambers 260 belonging to the same group may be provided with the same structure, and the process chambers 260 belonging to different groups may be provided with different structures.

The controller 900 may control the configurations of the substrate processing apparatus 10. The controller 900 may control the index module 100 and the process processing module 200. Further, the controller 900 may be configured to control the substrate processing apparatus provided in the process chamber 260.

Further, the controller 900 may include a process controller formed of a microprocessor (computer) that executes the control of the substrate processing apparatus 10, a user interface formed of a keyboard in which an operator performs a command input operation or the like in order to manage the substrate processing apparatus 10, a display for visualizing and displaying an operation situation of the substrate processing apparatus 10, and the like, and a storage unit storing a control program for executing the process executed in the substrate processing apparatus 10 under the control of the process controller or a program, that is, a treatment recipe, for executing the process in each component according to various data and processing conditions. Further, the user interface and the storage unit may be connected to the process controller. The processing recipe may be memorized in a storage medium in the storage unit, and the storage medium may be a hard disk, and may also be a portable disk, such as a CD-ROM or a DVD, or a semiconductor memory, such as a flash memory.

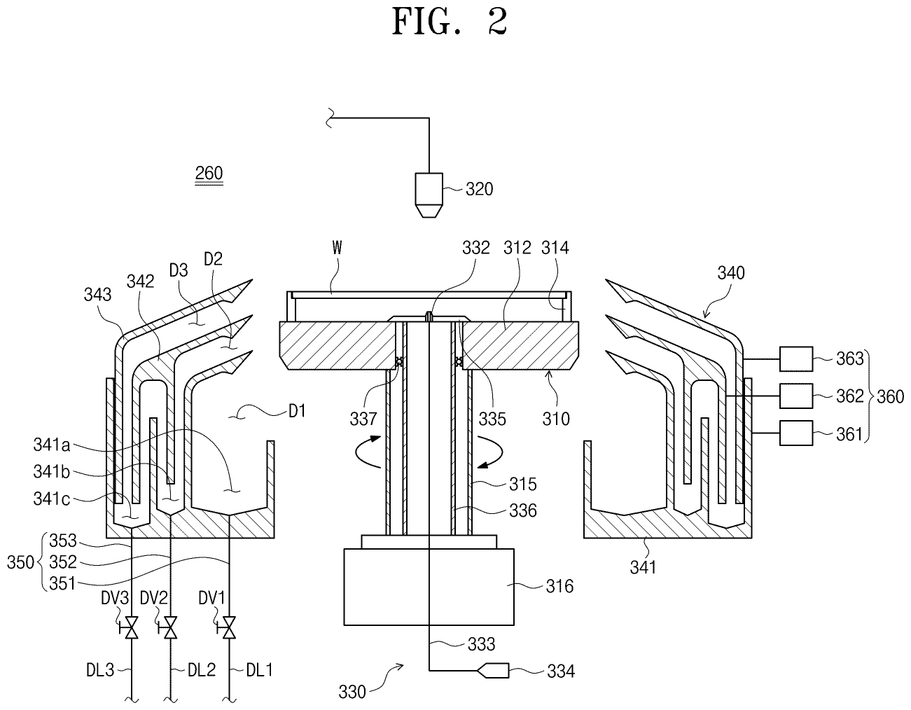

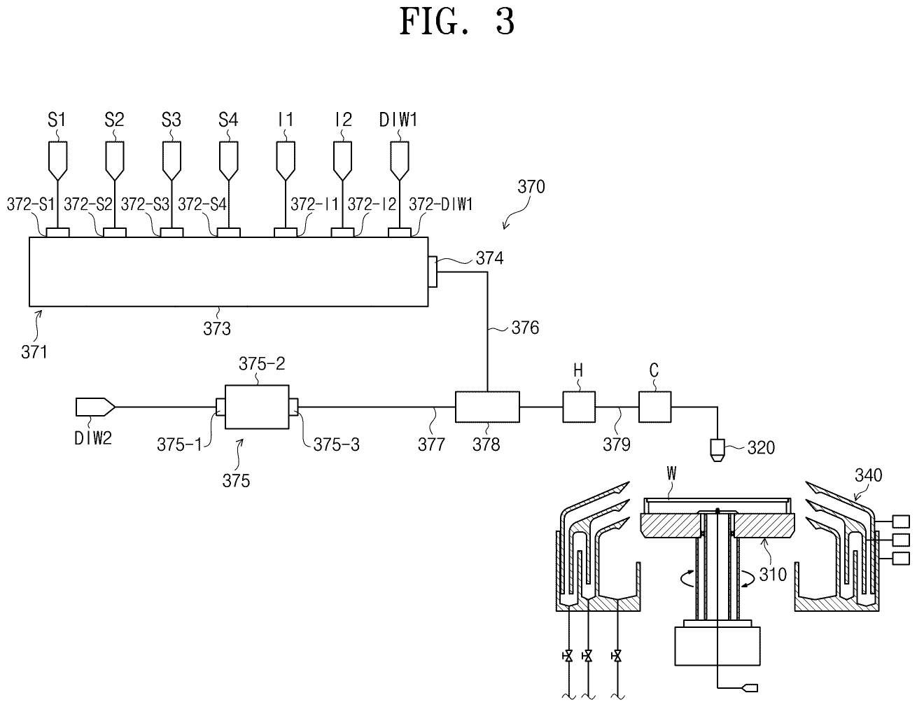

FIG. 2 is a cross-sectional view schematically illustrating a process chamber of FIG. 1, and FIG. 3 is a diagram illustrating an etchant supply unit that supplies an etchant to an etchant nozzle of FIG. 2.

Referring to FIGS. 2 and 3, the process chamber 260 may be provided with the substrate processing apparatus for liquid-treating the substrate W. The process chamber 260 may include a substrate support chuck 310, an etchant nozzle 320, a lower liquid supply unit 330, a cup 340, a drain line 350, a lifting driver 360, and an etchant supply unit 370.

The substrate support chuck 310 may support and rotate the substrate W. The substrate support chuck 310 may include a chuck body 312, a support pin 314, a rotating shaft 315, and a hollow motor 316.

The chuck body 312 may have a disk shape. The chuck body 312 may have an opening formed in a center region thereof. In the opening formed in the chuck body 312, some configurations of the lower liquid supply unit 330 described later may be inserted. The chuck body 312 may be configured to be rotatable.

The support pin 314 may be installed on the chuck body 312. The support pin 314 may be installed on the top of the chuck body 312. The support pin 314 may be configured to support a lateral portion and a bottom portion of the substrate W. The support pin 314 may be configured to support an edge region of the substrate W. The top end of the support pin 314 may be configured to include a first face supporting a bottom surface of the substrate W and a second face supporting a lateral portion of the substrate W.

The support pin 314 may be moveable in a horizontal direction by a mechanical mechanism, which may include a motor, rails, or the like (not illustrated) as needed 314.

The rotating shaft 315 may be connected to a lower portion of the chuck body 312. The rotating shaft 315 may rotate the chuck body 312. The rotating shaft 315 may be provided as a hollow shaft. The rotating shaft 315 may be configured to have an inner diameter equal to or larger than that of an opening formed in the center region of the chuck body 312. The interior of the rotating shaft 315 may be provided for insertion of the liquid supply shaft 336 of the lower liquid supply unit 330 described later.

An upper end of the rotating shaft 315 may be connected to the lower portion of the chuck body 312, and a lower end of the rotating shaft 315 may be connected to the hollow motor 316. The hollow motor 316 may rotate the rotating shaft 315. The hollow motor 316 may rotate the rotating shaft 315 to rotate the chuck body 312, which may rotate the substrate W placed on the support pin 314. As will be described later, the rotational force generated by the hollow motor 316 may not be transmitted to the liquid supply shaft 336, That is, the lower liquid supply unit 330 described later may be independent of the rotation of the chuck body 312.

The etchant nozzle 320 may supply an etchant to the substrate W. The etchant supplied by the etchant nozzle 320 may be supplied from the etchant supply unit 370 described later. The etchant nozzle 320 may be positioned on a rotational axis of the substrate W that is rotated by the substrate support chuck 310, and may be configured to supply an etchant to the center of the substrate W. The position of the etchant nozzle 320 may be changed by an arm (not illustrated), a motor, or the like. For example, the position of the etchant nozzle 320 may be changed between a process position positioned on the rotational axis of the substrate W and a standby position positioned at the upper side of a standby port (not illustrated).

The etchant supplied by the etchant nozzle 320 may be a liquid prepared by mixing an etching chemical, an etching inhibitor, and pure water. The etching chemical may be a chemical composed of hydrogen peroxide, acetic acid, an acid catalyst, or a combination thereof.

The acid catalyst may be an acid catalyst containing hydrogen. The acid catalyst may be provided as a chemical that is a stronger acid than acetic acid. Hydrogen peroxide and acetic acid may be used as reactants for the synthesis of peracetate. Acetic acid is a relatively weak acid. Because of this, it may be difficult for acetic acid to provide sufficient hydrogen (H) for the synthesis of peracetate. Accordingly, when the etching chemical includes an acid catalyst that contains hydrogen but is a stronger acid than acetic acid, the acid catalyst may provide a large amount of hydrogen (H), thereby making the synthesis of peracetate more effective. The acid catalyst may be, for example, methanesulfonic acid (MSA).

The etching inhibitor may be an inhibitor formed of a silicon etching inhibitor (Si inhibitor), a silicon oxide etching inhibitor (SiO₂ inhibitor), or a combination thereof.

The lower liquid supply unit 330 may supply a treatment liquid to the bottom of the substrate W. The lower liquid supply unit 330 may include a lower nozzle 332, a lower supply line 333, a lower supply source 334, a cover 335, a liquid supply shaft 336, and a bearing 337.

The lower nozzle 332 may be installed on the cover 335 to face the bottom center region of the substrate W. The cover 335 may prevent the treatment liquids supplied to the substrate W from entering the rotating shaft 315 or the liquid supply shaft 336 through the hollow formed in the chuck body 312. The lower nozzle 332 may be connected to the lower liquid supply line 333 that may be provided within the liquid supply shaft 336. The lower liquid supply line 333 is connected to the lower liquid supply source 334 and supply the lower nozzle 332 with the treatment liquid supplied by the lower liquid supply source 334. The treatment liquid supplied by the lower liquid supply source 334 may be an organic solvent, such as isopropyl alcohol (IPA), or deionized water (DI Water). The lower liquid supply source 334 may also heat the treatment liquid and supply the heated treatment liquid to the lower nozzle 332.

In addition, a bearing 337 may be provided between the liquid supply shaft 336 and the chuck body 312. The outer surface of the liquid supply shaft 336 and the chuck body 312 may be spaced apart by the bearing 337. Further, the rotational force provided by the hollow motor 316 by the bearing 337 may not be transmitted to the liquid supply shaft 336. That is, the lower liquid supply unit 330 may be independent with respect to the rotation provided by the hollow motor 316.

The cup 340 may be provided to surround the substrate support chuck 310. The cup 340 may be configured to recover the treatment liquid supplied to the substrate W by the etchant nozzle 320 and the substrate supply unit 330.

The cups 340 may include a first cup 341, a second cup 342, and a third cup 343. The first cup 341 may be an inner cup. The first cup 341 may define a first drain space 341a, a second drain space 341b, and a third drain space 341c. The first drain space 341a, the second drain space 341b, and the third drain space 341c may be spaces for recovering the treatment liquids that are supplied to the substrate W and scattered. For example, the first drain space 341a may be a space for recovering the etchant. Further, the second drain space 341b may be a space for recovering the etchant. Further, the third drain space 341c may be a space for recovering the wetting liquid and the removal liquid.

The first drain space 341a may be located adjacent to the chuck 310, the second drain space 341b may be located further from the chuck 310 than the first drain space 341a, and the third drain space 341c may be located further from the chuck 310 than the second drain space 341b.

Additionally, the drain line 350 may discharge liquids collected in the drain spaces 341a and 341c described above to the outside. The drain line 350 may include a first drain line 351 connected to the first drain space 341a, a second drain line 352 connected to the second drain space 341b, and a third drain line 353 connected to the third drain space 341c.

The first drain line 351 may be connected to a first valve DV1. The first valve DV1 may be a diaphragm valve. The first valve DV1 may be connected with a first discharge line DL1. The recovered treatment liquid may be discharged to the outside of the substrate treatment unit through the first discharge line DL1.

The second drain line 352 may be connected to a second valve DV2. The second valve DV2 may be a diaphragm valve. The second valve DV2 may be connected with a second discharge line DL2. The recovered treatment liquid may be discharged to the outside of the substrate treatment unit through second discharge line DL2.

The third drain line 353 may be connected to a third valve DV3. The third valve DV3 may be a diaphragm valve. The third valve DV3 may be connected with a third discharge line DL3. The recovered treatment liquid may be discharged to the outside of the substrate treatment unit through the third discharge line DL3.

The second cup 342 may be a middle cup. The third cup 343 may be an outer cup. The first cup 341 may define a first recovery path DI corresponding to the first drain space 341a. The first cup 341 and the second cup 342 may be combined with each other to define a second recovery path D2 corresponding to the second drain space 341b. The second cup 342 and the third cup 343 may be combined with each other to define a third recovery path D3.

The lifting driver 360 may lift the cups 340. The lifting driver 360 may lift the first cup 341, the second cup 342, and the third cup 343 independently of each other. The lifting driver 360 may include a first lifting driver 361 for lifting the first cup 341, a second lifting driver 362 for lifting the second cup 342, and a third lifting driver 363 for lifting the third cup 343. The lifting driver 360 may adjust the heights of the cups 351, 352, and 353 to adjust the heights of the recovery paths D1 and D2 described above, and the gap of the recovery paths D1 and D2.

The etchant supply unit 370 may supply an etchant to the etchant nozzle 320. The etchant supply unit 370 may supply an etchant ETC, which is a treatment liquid prepared by mixing an etching chemical, an etching inhibitor, and pure water, to the etchant nozzle 320. The etchant supply unit 370 may include a first valve module 371, a second valve module 375, a first connection line 376, a second connection line 377, a mixer 378, an etchant supply line 379, a heater H, and a chiller C.

The first valve module 371 may be connected to a first chemical supply source S1, a second chemical supply source S2, a third chemical supply source S3, a fourth chemical supply source S4, a first inhibitor supply source I1, a second inhibitor supply source I2, and a first deionized water supply source DIW1. The first chemical supply source S1, the second chemical supply source S2, the third chemical supply source S3, and the fourth chemical supply source S4 may be etching chemical supply sources. The etching chemical supply source may supply an etching chemical. The first inhibitor supply source I1 and the second inhibitor supply source I2 may be etching inhibitor supply sources. The etching inhibitor supply source may supply an etching inhibitor.

The first chemical supply source S1 may supply hydrogen peroxide water (H₂O₂) to the housing 373. The first chemical supply source S1 may be configured to include a configuration, such as a tank and a flow rate regulating valve, to store and supply hydrogen peroxide, and to regulate a supply flow rate per unit time of hydrogen peroxide supplied to the housing 373.

The second chemical supply source S2 may supply acetic acid (CH₃COOH) to the housing 373. The second chemical supply source S2 may be configured to include a configuration, such as a tank and a flow rate regulating valve, to store and supply acetic acid and to regulate a supply flow rate per unit time of acetic acid supplied to the housing 373.

The third chemical supply source S3 may supply an acid catalyst, such as methane sulfonic acid (MSA), to the housing 373. The second chemical supply source S2 may be configured to include a configuration, such as a tank and a flow rate regulating valve, to store and supply methanesulfonic acid, and to regulate a supply flow rate per unit time of methanesulfonic acid supplied to the housing 373.

The fourth chemical supply source S4 may supply hydrofluoric acid (HF) to the housing 373. The fourth chemical supply source S4 may be configured to include a configuration, such as a tank and a flow rate regulating valve, to store and supply hydrofluoric acid (HF) and to regulate a supply flow rate per unit time of hydrofluoric acid supplied to the housing 373.

The first inhibitor supply source I1 may supply silicone etching inhibitor (Si inhibitor) to the housing 373. The first inhibitor supply source I1 may be configured to include a configuration, such as a tank and a flow rate regulating valve, to store and supply the silicon etching inhibitor and to regulate a supply flow rate per unit time of the silicon etching inhibitor supplied to the housing 373. The silicone etching inhibitor may be an organic solvent.

The second inhibitor supply source 12 may supply a silicon oxide etching inhibitor (SiO₂ inhibitor) to the housing 373. The second inhibitor supply source 12 may be configured to include a configuration, such as a tank and a flow control valve, to store and supply the silicon oxide etching inhibitor, and to regulate a supply flow rate per unit time of the silicon oxide etching inhibitor supplied to the housing 373. The silicon oxide etching inhibitor may be an organic solvent. For example, the silicon oxide etching inhibitor may be octyl acetate.

The first deionized water supply source DIW1 may supply deionized water to the housing 373. The first deionized water supply source DIW1 may be configured to include a configuration, such as a tank and a flow regulating valve, to store and supply deionized water, and to regulate a supply flow rate per unit time of deionized water supplied to the housing 373.

The first valve module 371 may include an inlet 372, a housing 373, and an outlet 374.

The inlet 372 may be provided in the housing 373, which will be described later. The inlet 372 may be provided as a separate body from the housing 373, and coupled to the housing 373, or alternatively, may be formed as a hole in the housing 373 itself.

The inlet 372 may be provided with a plurality of inlets. For example, the first valve module 371 may be provided with an inlet 372-S1 connected with the first chemical supply source S1, an inlet 372-S1 connected with the first chemical supply source S1, an inlet 372-S2 connected with the second chemical supply source S2, an inlet 372-S2 connected with the third chemical supply source S3, and an inlet 372-S3 connected with the fourth chemical supply source S4, an inlet 372-S4 connected with the fourth chemical supply source S4, an inlet 372-I1 connected with the first inhibitor supply source I1, an inlet 372-I2 connected with the second inhibitor supply source I2, and an inlet 372-DIW1 connected with the first deionized water supply source DIW1. Each of the inlets 372 may be configured to change their aperture, such that the flow rate of liquid introduced into the interior space of the housing 373 is adjustable.

The housing 373 may have an interior space in which the first to fourth chemicals, the first to second inhibitors, and the deionized water may be mixed. The housing 373 may be provided to have a barrel shape.

The outlet 374 may be provided in the housing 373 described above. The outlet 374 may be provided as a separate body from the housing 373 and coupled to the housing 373, or alternatively, the outlet 374 may be formed as a hole in the housing 373 itself.

The outlet 374 may be in fluid communication with the mixer 378 via the first connection line 376. A mixed liquid of etching chemical, etching inhibitor, and deionized water flowing out of the outlet 374 may be supplied to the mixer 378. The mixed liquid supplied to the mixer 378 via the first connection line 376 may be supplied at a lower volume per unit time than the deionized water supplied to the mixer 378 via the second connection line 377, which will be described later (low volume supply).

The second valve module 375 may include an inlet 375-1, a housing 375-2, and an outlet 375-3. The inlet 375-1 and the outlet 375-3 may each be configured to have an adjustable opening. This allows the supply flow rate per unit time of deionized water supplied to the mixer 378 to be adjusted.

The second valve module 375 may be connected to a second deionized water supply source DIW2. The second deionized water supply source DIW2 may supply deionized water to the housing 375-2. The second deionized water supply source DIW2 may be configured to include a configuration such as a tank and a flow regulating valve to store and supply deionized water, and to regulate a supply flow rate per unit time of deionized water supplied to the housing 375-2.

The outlet 375-3 may be in fluid communication with the mixer 378 via the second connection line 377. Deionized water flowing out through the outlet 375-3 may be supplied to the mixer 378. The deionized water supplied to the mixer 378 via the second connection line 377 may have a higher supply flow rate per unit time than the mixed liquid supplied to the mixer 378 via the first supply line 376 described above (large volume supply).

The mixer 378 may mix the mixed liquid supplied through the first valve module 371 and the deionized water supplied through the second valve module 375. The mixer 378 may be provided with a barrel-shaped body having an internal space, and a stirrer or the like that stirs the mixed liquid and deionized water by a screw member or a motor or the like that generates a vortex so that the mixed liquid and deionized water may be mixed smoothly in the internal space provided by the body. In the mixer 378, the mixed liquid and the deionized water may be mixed to produce an etchant ETC.

Additionally, the mixer 378 may include an outlet (not illustrated) whose opening rate may be adjustable in response to an electrical signal, and the outlet may be connected to an etchant supply line 379. This allows for controlling the supply flow rate per unit time of the etchant ETC supplied to the etchant nozzle 320 via the mixer 378.

The etchant ETC, which is prepared by mixing the mixed liquid and the deionized water in the mixer 378, may be supplied to the etchant nozzle 320 via the etchant supply line 379. In the etchant supply line 379, a heater H and a chiller C may be installed to regulate the temperature of the etchant ETC supplied to the etchant nozzle 320. The heater H may be a block heater or a jacketed heater configured to heat the etchant supply line 379 to increase the temperature of the etchant ETC. Additionally, the chiller C may be a block chiller or a jacketed chiller configured to cool the etchant supply line 379 to reduce the temperature of the etchant ETC.

Hereinafter, a substrate processing method according to an exemplary embodiment of the present invention will be described in detail. The substrate processing method described hereinafter may be a semiconductor device manufacturing method for processing a substrate W, such as a wafer, to manufacture a semiconductor device having a 3D structure, such as a Gate All Around (GAA) or Complementary FET (CFET) structure. Further, to implement the substrate processing method described hereinafter, the substrate processing apparatus 10 may operate. For example, the controller 900 may generate control signals to control configurations of the substrate processing apparatus 10, such as the first valve module 371 and the second valve module 375 of the process chamber 260. The controller 900 may also include, or may be configured to include hardware circuitry or be software programmed to generate control signals to control the etching chemical supply sources S1, S2, S3, and S4, the etching inhibitor supply sources I1 and I2, the deionized water supply sources DIW1 and DIW2, the valve modules 371 and 375, the heater H, the chiller C, the mixer 378, and the like.

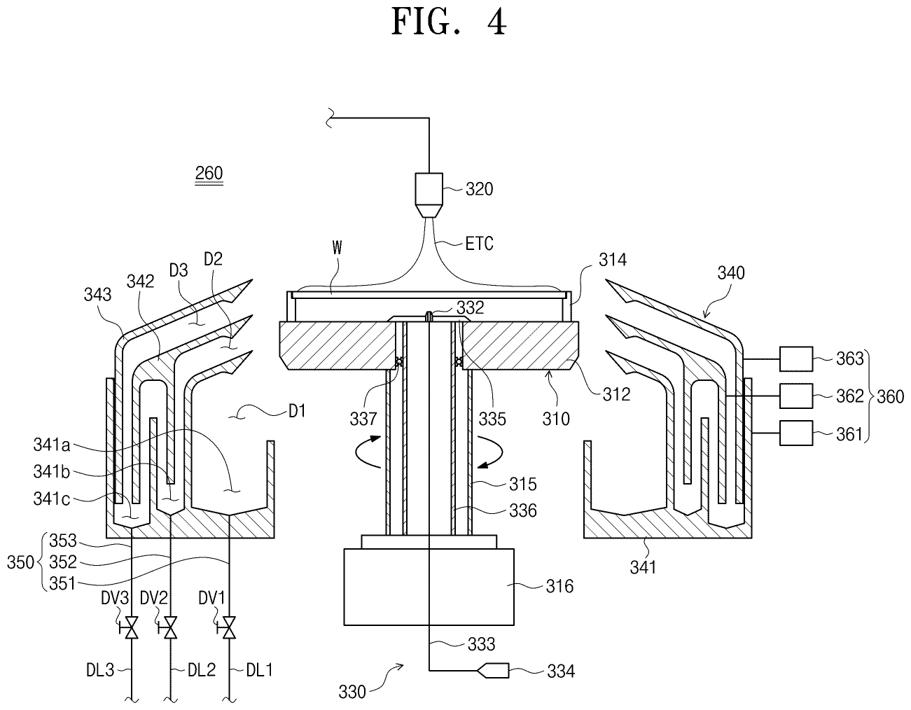

FIG. 4 is a diagram illustrating processing a substrate in the process chamber of FIG. 2.

Referring to FIG. 4, in a substrate processing method according to an exemplary embodiment of the present invention, the etchant nozzle 320 supplies an etchant ETC to a substrate W supported and rotated by the substrate support chuck 310 to remove a film provided on the substrate W, for example, a layer (an example of a first layer) that is a film composed of silicon germanium (SiGe).

The etchant ETC according to the exemplary embodiment of the present invention may be a liquid in which an etching chemical, an etching inhibitor, and deionized water are mixed.

The etching chemical may be a chemical composed of hydrogen peroxide, acetic acid, an acid catalyst (methanesulfonic acid), hydrofluoric acid, or a combination thereof.

The etchant ETC according to the exemplary embodiment of the present invention may be prepared using hydrogen peroxide, acetic acid and an acid catalyst (methanesulfonic acid (MSA)).

Hydrogen peroxide, acetic acid and methanesulfonic acid react to produce peracetic acid (CH₃COOOH). Peracetic acid oxidizes silicon germanium (SiGe) to produce SiO₂ and GeO₂. SiO₂ and GeO₂ may be transformed into (NH₄)₂SiF₆, H₂GeF₆, and the like by dissociated hydrofluoric acid (HF).

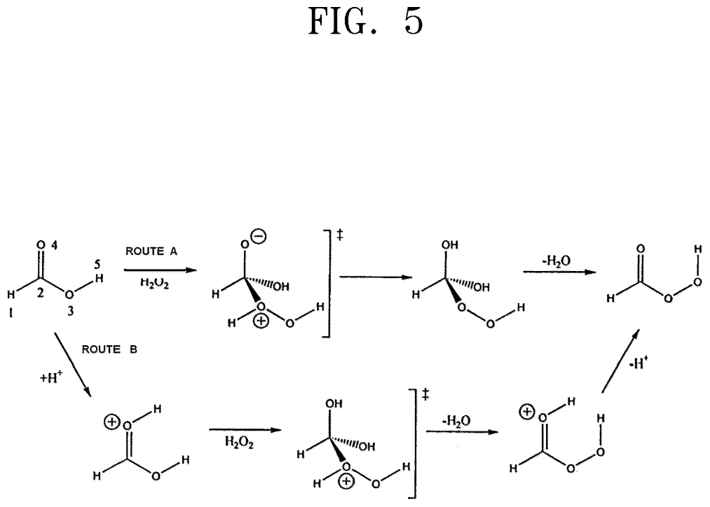

FIG. 5 is a diagram illustrating a comparative view of generation routes of peracetic acid without the addition of MSA and with the addition of MSA.

Referring to FIG. 5, Route A is the case where the etchant does not include methanesulfonic acid, and Route B is the case where the etchant includes methanesulfonic acid. Because methanesulfonic acid is very strongly acidic, Route B with added methanesulfonic acid reacts much faster than Route A without methanesulfonic acid. In other words, the addition of methanesulfonic acid speeds up the production of peracetic acid.

As previously described, the etching of silicon germanium is accomplished in the form in which peracetic acid oxidizes silicon germanium, and the oxide prepared by the oxidation of the silicon germanium is removed by hydrofluoric acid. In other words, when the amount of peracetic acid generated is large, the etch rate on silicon germanium is high. On the other hand, when the amount of peracetic acid generated is small, the etch rate on silicon germanium is low.

In other words, when it is desired to increase the etch rate for silicon germanium, the proportions of hydrogen peroxide, acetic acid, and methanesulfonic acid used in the preparation of the etchant are increased, and when it is desired to decrease the etch rate, the proportions of hydrogen peroxide, acetic acid, and methanesulfonic acid are decreased.

Furthermore, the etch rate for silicon germanium (SiGe) may vary depending on the temperature of the etchant ETC. For example, when the temperature of the etchant ETC is high, the reactivity between the silicon germanium and the peracetic acid and dissociated hydrofluoric acid increases, so that the etch rate may be high, and conversely, when the temperature of the etchant ETC is low, the etch rate may be low.

Furthermore, as will be described later, a film (an example of a second layer) composed of a material other than silicon germanium (SiGe) may be provided on the substrate W. For example, the material other than silicon germanium (SiGe) may be silicon (Si) or silicon oxide (SiO₂).

In order to increase the selectivity for silicon germanium (SiGe), the etch rate for silicon (Si) or silicon oxide (SiO₂) may be reduced. In order to decrease the selectivity for silicon germanium (SiGe), the etch rate for silicon (Si) or silicon oxide (SiO₂) may be increased.

The etch rate for silicon (Si) or silicon oxide (SiO₂) depends on the degree of dissociation of hydrofluoric acid (HF). As the dissociation of hydrofluoric acid (HF) increases, the etch rate increases, and as the degree of dissociation of HF decreases, the etch rate decreases. The degree of dissociation of hydrofluoric acid (HF) may vary depending on the proportion of the silicone etching inhibitor or silicon oxide etching inhibitor described above. For example, increasing the proportion of organic solvent, which may be a silicone etching inhibitor or a silicon oxide etching inhibitor, lowers the dissociation of hydrofluoric acid. Conversely, decreasing the proportion of organic solvent increases the degree of dissociation of hydrofluoric acid. In other words, by adjusting the proportion of the etching inhibitor, the selectivity of silicon germanium (SiGe) may be adjusted.

However, when the proportion of organic solvent is increased excessively to increase the selectivity of SiGe, the SiGe itself may not be etched properly. The organic solvent controls the degree of dissociation of hydrofluoric acid, and when the degree of dissociation of hydrofluoric acid is excessively low, it may be difficult to remove SiO₂, GeO₂, and the like generated by the reaction with peracetic acid. Therefore, it is necessary to control the selectivity of silicon germanium according to the required process.

In other words, the etchant supply unit 370 according to the exemplary embodiment of the present invention may be configured to: i) increase or decrease the proportions of hydrogen peroxide, acetic acid, and methanesulfonic acid; ii) increase or decrease the proportion of an organic solvent, which may be a silicon etching inhibitor or a silicon oxide etching inhibitor; and iii) increase or decrease the temperature of the etchant, so as to adjust the etch rate and etch selectivity of the silicon germanium according to the process conditions.

The proportions of hydrogen peroxide, acetic acid, and methanesulfonic acid may be varied by adjusting the amount of chemicals supplied per unit time from the first or third chemical source S1, S2, and S3, and/or by adjusting the opening rates of the inlets 372-S1, 372-S2, 372-S3, and 372-S4.

The proportion of organic solvent may be varied by adjusting the amount of inhibitor supplied per unit time from the first and second inhibitor sources I1 and I2, or by adjusting the opening rates of the inlets 372-I1 and 372-I2.

The temperature of the etchant ETC may be varied through the operation of the heater H or the chiller C.

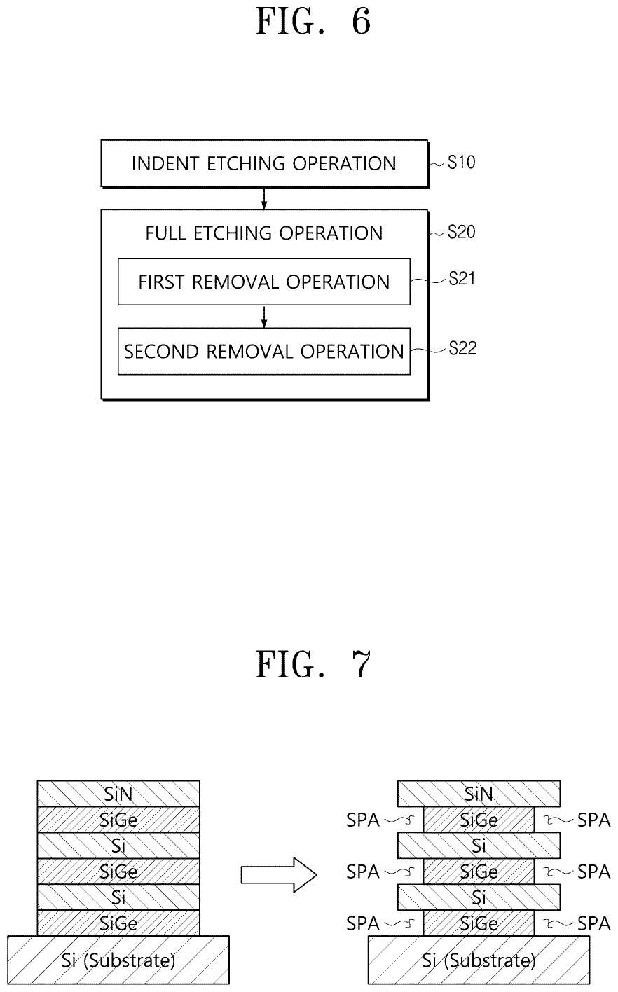

FIG. 6 is a flow chart illustrating the substrate processing method according to an exemplary embodiment of the present invention.

The substrate processing method according to the exemplary embodiment of the present invention may be used to manufacture a semiconductor device including a GAA structure. In manufacturing a semiconductor device comprising a GAA structure, the substrate processing apparatus 10 of the present invention may perform an indent etching operation S10 and a full etching operation S20. The indent etching operation S10 and the full etching operation S20 may be performed sequentially. Other processes may be performed between the indent etching operation S10 and the full etching operation S20. For example, the other process may be a deposition process to form a film on the substrate W, or a process to form a gate such as a source/drain.

FIG. 7 is a diagram illustrating the removal of a film formed on the substrate when performing the indent etching of FIG. 6.

Referring to FIGS. 6 and 7, a feature structure is provided on the substrate W in which a first layer composed of germanium (SiGe) and a second layer composed of a silicon material different from silicon germanium (e.g., silicon (Si)) are alternately stacked.

In the indent etching operation S10 (one example of a pre-etching operation), a process is performed to remove a portion of the first layer composed of silicon germanium (SiGe) without removing the entirety of the first layer. In other words, in the indent etching operation S10, the center portion of the first layer is left, and only the edge portion is removed to form a space (SPA).

In this case, in the indent etching operation S10, it is necessary to reduce the etch rate for silicon germanium (SiGe) because the SiGe should not be completely removed. In addition, the selectivity for silicon (Si) needs to be increased.

Therefore, when preparing the etchant ETC supplied in the indent etching operation S10, the proportions of hydrogen peroxide, acetic acid, and methanesulfonic acid may be decreased, the proportion of organic solvent may be increased, and the temperature of the etchant ETC may be decreased. In this case, the proportion of deionized water may be increased as the proportion of organic solvent is increased.

Furthermore, depending on the type of material in contact with the silicon germanium, only one of the silicon etching inhibitor and the silicon oxide etching inhibitor may be used, or both may be used.

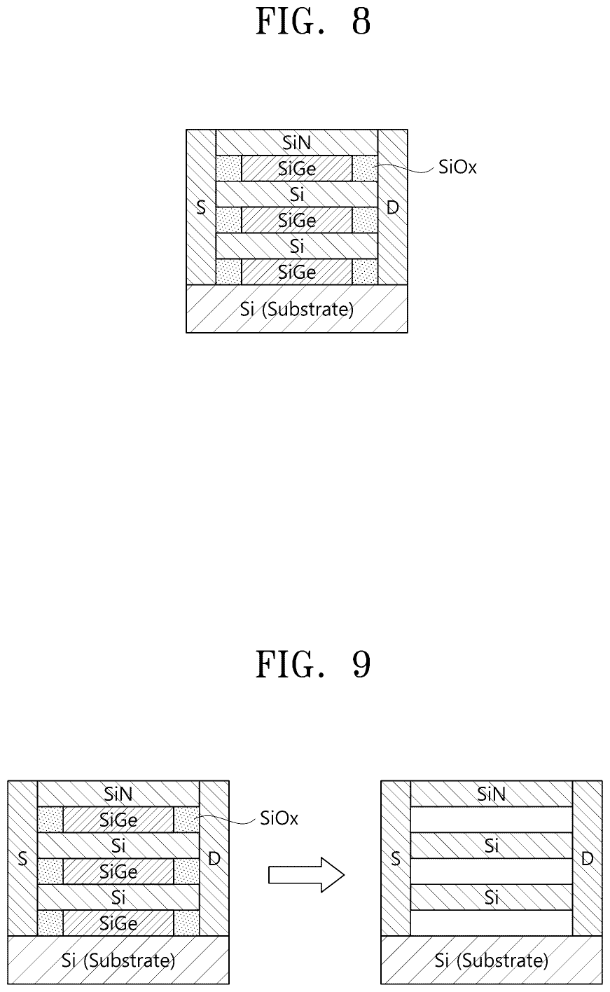

FIG. 8 is a diagram illustrating the appearance of a substrate after performing an indent etching operation, followed by an intermediate process on the substrate.

After the intermediate process, silicon germanium (SiGe) and silicon (Si) are alternately stacked on the Si Substrate, and SiOx (e.g., SiO₂) may be deposited in the space SPA portion. Furthermore, a source S and a drain D of the GAA structure are formed on opposite sides of the second layer composed of silicon (Si). The source and the drain are formed to include a silicon germanium (SiGe) material.

The second layer composed of silicon (Si) functions as a channel of the GAA structure, and the first layer composed of silicon germanium (SiGe) is removed by the full etching S20 described later.

The reason for performing the indent etching operation S10 first, rather than directly performing the full etching operation S20 described later, is that the source S and the drain D are composed of silicon germanium material. More specifically, when the first layer composed of silicon germanium (SiGe) is entirely removed by performing the full etching operation S20 directly without performing the indent etching operation S10, the source and the drain are composed of silicon germanium, so that the source/drain may be removed along with the first layer. Therefore, the present invention forms the space SPA in which a deposition film may be formed by the indent etching S1, and makes the first layer be spaced apart from the source/drain, so that the source/drain may be minimized from being etched when the first layer is completely removed.

Furthermore, in the indent etching operation S10, it is necessary to etch the silicon germanium to be thin with a thickness of 5 nm or less, because when the size of the space SPA is formed too thick, the width of the channel in which the second layer composed of silicon (Si) will function is reduced, thereby reducing the size of the current that may flow. To this end, in the exemplary embodiment of the present invention, the temperature of the etching chemical, the etching inhibitor, and the etchant may be set in advance through preliminary experiments.

FIG. 9 is a diagram illustrating the removal of a film formed on the substrate when performing the pull etching of FIG. 6.

Referring to FIGS. 6 and 9, the full etching operation S20 may include complete removal of the first layer composed of silicon germanium (SiGe). Since the full etching operation S20 requires removal of all of the remaining first layer composed of silicon germanium (SiGe), it is necessary to increase the etch rate for silicon germanium. To prevent the etch rate of silicon germanium from being lowered by the etching inhibitor, the proportion of organic solvent may be lowered.

In other words, when preparing the etchant ETC supplied in the full etching operation S20, the proportions of hydrogen peroxide, acetic acid, and methanesulfonic acid may be increased, the proportion of organic solvent may be decreased, and the temperature of the etchant ETC may be increased. In this case, the proportion of deionized water may be increased as the proportion of organic solvent is decreased. Thus, the full etching operation S20 may be performed faster than the indent etching operation S10.

Furthermore, the full etching operation S20 may be performed in two operations, when necessary.

A first removal operation S21, which corresponds to the beginning of the full etching operation S20, may be performed with the proportions of hydrogen peroxide, acetic acid, and methanesulfonic acid in the etchant ETC may be performed a first proportion, which is a relatively high proportion. By doing so, the time required for the etching process may be shortened. Furthermore, in the first removal operation, it may be considered to increase the temperature of the etchant ETC by means of the heater H.

A second removal operation S21, which corresponds to the latter part of the full etching operation S20 may be performed with the proportion of hydrogen peroxide, acetic acid, and methanesulfonic acid in the etchant ETC at a second proportion, which is a relatively low proportion. The second proportion may be lower than the first proportion. Also, in the second removal operation, it may be considered to lower the temperature of the etchant ETC through the chiller C.

This is because in the latter part of the full etching operation S20, when the etch rate is excessively high, even the source/drain may be etched in some cases.

Furthermore, in the first removal operation S21, the proportion of the etching inhibitor is adjusted to an A proportion, and in the second removal operation S22, the proportion of the etching inhibitor is adjusted to a B proportion, which is higher than the A proportion. In other words, in the latter part of the full etching operation S20, the proportion of organic solvent may be increased to increase the etch selectivity for silicon germanium. This enables precise removal of only silicon germanium (SiGe) from the feature structure.

Furthermore, in the indent etching operation S1, which corresponds to the pre-etching operation, the proportion of the etching chemical may be adjusted to a P proportion. The P proportion may be a proportion that is lower than the first proportion and lower than the second proportion. Alternatively, the P proportion may be a proportion that is lower than the first proportion and higher than the second proportion.

In the present invention, during the process of the etchant supply unit 370, hydrogen peroxide, acetic acid, and methanesulfonic acid are provided to have variable proportions, so that the silicon germanium (SiGe) may be removed quickly in the first removal operation S21 and the second removal operation S22 may be performed when the silicon (Si) or silicon oxide (SiO₂) is almost reached in the etchant, thereby increasing the selectivity of the silicon germanium (SiGe).

In the present invention, it is also possible to adjust the width of the channel formed by the silicon (Si) by adjusting the etch rate of the silicon germanium (SiGe). For example, the etch rate of silicon germanium may be increased when the width of the channel is desired to be narrowed, and the etch rate of silicon germanium may be decreased when the width of the channel is desired to be widened. As the width of the channel varies, the magnitude of the current flowing through the semiconductor device varies, so the magnitude of the current flowing through the semiconductor device may be determined by adjusting the etch rate of the silicon germanium.

In other words, the present invention makes it possible to control the etch rate and etch selectivity of silicon germanium (SiGe) by the etchant ETC via the etchant supply unit 370, making it possible to perform both the indent etching operation S1 and the full etching operation S2 with only one substrate processing apparatus 10.

Further, in the exemplary embodiments of the present invention, it is possible to selectively and effectively remove silicon germanium (SiGe) from the feature structure in which silicon germanium (SiGe) and silicon (Si) (or silicon oxide (SiO₂)) are alternately stacked. Thus, in the examples described above, the present invention has been described based on the case where the 3D structure included in the semiconductor device is the GAA structure as an example, but is not limited thereto. For example, the 3D structure included in the semiconductor device may be a CFET structure. A CFET structure may be a structure including nMOS and/or pMOS, and more specifically, may have a structure in which multiple GAA structures are stacked.

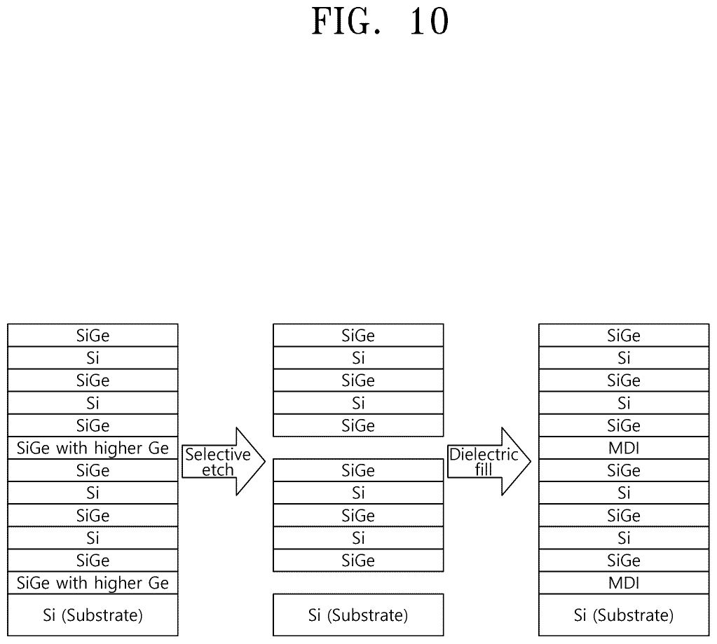

Accordingly, as illustrated in FIG. 10, the process of fabricating a CFET may require an operation of removing silicon germanium, similar to that of fabricating the GAA. Thus, the substrate processing method according to the exemplary embodiment of the present invention may be similarly applied to the process of fabricating CFET.

It should be understood that exemplary embodiments are disclosed herein and that other variations may be possible. Individual elements or features of a particular exemplary embodiment are not generally limited to the particular exemplary embodiment, but are interchangeable and may be used in selected exemplary embodiments, where applicable, even when not specifically illustrated or described. The modifications are not to be considered as departing from the spirit and scope of the present invention, and all such modifications that would be obvious to one of ordinary skill in the art are intended to be included within the scope of the accompanying claims.

1. A method of processing a substrate, the method comprising:
supplying an etchant for removing silicon germanium (SiGe) provided on a substrate to the substrate, the etchant being prepared with an etching chemical and an etching inhibitor,
wherein an etch rate for the silicon germanium and/or an etch selectivity for the silicon germanium is controlled by adjusting a proportion of at least one of the etching chemical and the etching inhibitor used in the preparation of the etchant.

2. The method of claim 1, wherein in order to increase the etch rate for the silicon germanium, the proportion of the etching chemical is increased, and
in order to decrease the etch rate for the silicon germanium, the proportion of the etching chemical is decreased.

3. The method of claim 1, wherein the etching chemical is an acid catalyst including hydrogen peroxide, acetic acid, and hydrogen, hydrofluoric acid, or a combination thereof, in which the acid catalyst is a stronger acid than the acetic acid.

4. The method of claim 1, wherein a material different from the silicon germanium is provided on the substrate,
in order to increase the etch selectivity of the silicon germanium to the material, the proportion of the etching inhibitor is increased, and
in order to increase the etch selectivity of the silicon germanium to the material, the proportion of the etching inhibitor is decreased.

5. The method of claim 4, wherein the material includes at least one of silicon (Si) and silicon oxide (SiOx), and
the etching inhibitor is an inhibitor formed of a silicon etching inhibitor, a silicon oxide etching inhibitor, or a combination thereof.

6. The method of claim 1, wherein a silicon material different from the silicon germanium is further provided on the substrate,
the etchant selectively removes the silicon germanium from the silicon material,
in a removal operation to remove the silicon germanium, the proportion of the etching chemical in the etchant is a first proportion, and
in a second removal operation, performed after the first removal operation, to remove the silicon germanium, the proportion of the etching chemical in the etchant is adjusted to be a second proportion lower than the first proportion.

7. The method of claim 6, wherein in the first removal operation, the proportion of the etching inhibitor used in the preparation of the etchant is an A proportion, and
in the second removal operation, the proportion of the etching inhibitor used in the preparation of the etchant is adjusted to be a B proportion higher than the A proportion.

8. The method of claim 6, wherein in a pre-etching operation, performed prior to the first removal operation, to remove only a portion of the silicon germanium, the proportion of the etching chemical used in the preparation of the etchant is adjusted to be a P proportion lower than the first proportion or the second proportion.

9. The method of claim 1, wherein the adjustment of the proportion of the etching chemical or the etching inhibitor is accomplished by adjusting a supply flow rate per unit time of the etching chemical or the etching inhibitor supplied to a mixer where the etching chemical, the etching inhibitor, and deionized water are mixed.

10. A manufacturing method, in which a feature structure is provided in which a first layer composed of silicon germanium and a second layer composed of a silicon material different from the silicon germanium are alternately stacked, the silicon material being any one of silicon and silicon oxide, the manufacturing method comprising:
an indent etching operation of supplying an etchant to the feature structure to remove only a portion of the first layer; and
a full etching operation of supplying the etchant to the feature structure to remove a remainder of the first layer that has not been removed in the indent etching operation,
wherein a proportion of an etching chemical used in a preparation of the etchant supplied in the indent etching operation is different from a proportion of an etching chemical used in a preparation of the etchant supplied in the pull etching operation.

11. The manufacturing method of claim 10, wherein the proportion of the etching chemical used in the preparation of the etchant supplied in the indent etching operation is lower than the proportion of the etching chemical used in the preparation of the etchant supplied in the full etching operation.

12. The manufacturing method of claim 11, wherein the proportion of the etching inhibitor used in the preparation of the etchant supplied in the indent etching operation is higher than the proportion of the etching inhibitor used in the preparation of the etchant supplied in the full etching operation.

13. The manufacturing method of claim 11, wherein the full etching operation includes:
a first removal operation; and
a second removal operation performed after the first removal operation, and
a proportion of the etching chemical used in the preparation of the etchant supplied in the first removal operation is higher than a proportion of the etching chemical used in the preparation of the etchant supplied in the second removal operation.

14. The manufacturing method of claim 13, wherein a proportion of the etching inhibitor used in the preparation of the etchant supplied in the first removal operation is lower than a proportion of the etching inhibitor used in the preparation of the etchant supplied in the second removal operation.

15. The manufacturing method of claim 13, wherein a temperature of the etchant supplied in the first removal operation is higher than a temperature of the etchant supplied in the second removal operation.

16. The manufacturing method of claim 10, wherein the manufacturing method is a method of manufacturing a semiconductor device having a Gate All Around (GAA) structure.

17. The manufacturing method of claim 10, wherein the manufacturing method is a method of manufacturing a semiconductor device having a Complementary PET (CFET) structure.

18-20. (canceled)
